(19) United States
(12) Patent Application Publication
(10) Pub. No.: US 2009/0201722 A1
(43) Pub. Date: Aug. 13, 2009

(54) METHOD INCLUDING MAGNETIC DOMAIN PATTERNING USING PLASMA ION IMPLANTATION FOR MRAM FABRICATION

(76) Inventors: Kamesh Giridhar, Bangalore Karnataka (IN); Omkaram Nalamasu, San Jose, CA (US); Steven Verhaverbeke, San Francisco, CA (US); Mahalingam Venkatesan, San Jose, CA (US)

Correspondence Address: APPLIED MATERIALS;C/O PILLSBURY WINTHROP SHAW PITTMAN LLP, P .O . BOX 10500, MCLEAN, VA, 22120, US

(21) Appl. No.: 12/355,612

(22) Filed: Jan. 16, 2009

Related U.S. Application Data
(63) Continuation-in-part of application No. 12/029,601, filed on Feb. 12, 2008.

(51) Int. Cl. G11C 11/15; G11B 5/66; H05B 6/00

(52) U.S. Cl. 365/173; 428/832; 428/831; 428/827; 428/828; 264/427; 977/887

(57) ABSTRACT

A method for defining magnetic domains in a magnetic thin film on a substrate, includes: coating the magnetic thin film with a resist; patterning the resist, wherein areas of the magnetic thin film are substantially uncovered; and exposing the magnetic thin film to a plasma, wherein plasma ions penetrate the substantially uncovered areas of the magnetic thin film, rendering the substantially uncovered areas non-magnetic. A tool for this process comprises: a vacuum chamber held at earth potential; a gas inlet valve configured to leak controlled amounts of gas into the chamber; a disk mounting device configured to (1) fit within the chamber, (2) hold a multiplicity of disks, spacing the multiplicity of disks wherein both sides of each of the multiplicity of disks is exposed and (3) make electrical contact to the multiplicity of disks; and a radio frequency signal generator electrically coupled to the disk mounting device and the chamber, whereby a plasma can be ignited in the chamber and the disks are exposed to plasma ions uniformly on both sides. This process may be used to fabricate memory devices, including magnetoresistive random access memory devices.

### CROSS-REFERENCE TO RELATED APPLICATIONS

This application is a Continuation in Part of U.S. application Ser. No. 12/029,601, filed Feb. 12, 2008.

### FIELD OF THE INVENTION

The present invention relates generally to definition of magnetic domains in magnetic information storage media such as magnetoresistive random access memories (MRAMs), and more particularly to methods of fabricating MRAMs including defining magnetic domains in magnetic thin films by using plasma ion implantation.

### BACKGROUND OF THE INVENTION

There is an ever present need for higher density information storage media for computers. Currently, the prevalent storage media is the hard disk drive (HDD). An HDD is a non-volatile storage device which stores digitally encoded data on rapidly rotating disks with magnetic surfaces. The disks are circular, with a central hole. The disks are made from a non-magnetic material, usually glass or aluminum, and are coated on both sides with magnetic thin films, such as cobalt-based alloy thin films. HDDs record data by magnetizing regions of the magnetic film with one of two particular orientations, allowing binary data storage in the film. The stored data is read by detecting the orientation of the magnetized regions of the film. A typical HDD design consists of a spindle which holds multiple disks, spaced sufficiently to allow read-write heads to access both sides of all of the disks. The disks are fixed to the spindle by clamps inserted into the central holes in the disks. The disks are spun at very high speeds. Information is written onto and read off a disk as it rotates past the read-write heads. The heads move in very close proximity to the surface of the magnetic thin film. The read-write head is used to detect and/or modify the magnetization of the material immediately underneath it. There is one head for each magnetic disk surface on the spindle. An arm moves the heads across the disks as they spin, allowing each head to access almost the entire surface of a disk.

The magnetic surface of each disk is divided into many small sub-micrometer-sized magnetic regions, referred to as magnetic domains, each of which is used to encode a single binary unit of information, referred to as a bit. Each magnetic region forms a magnetic dipole which generates a highly localized magnetic field. The write head magnetizes a magnetic region by generating a strong local magnetic field while in very close proximity to the magnetic thin film. The read head detects the orientation of the magnetic field in each region.

Where domains with different spin orientations meet there is a region referred to as a Bloch wall in which the spin orientation goes through a transition from the first orientation to the second. The width of this transition region limits the areal density of information storage. Consequently, there is a need to overcome the limit due to the width of Bloch walls.

To overcome the limit due to Bloch wall width in continuous magnetic thin films the domains can be physically separated by a non-magnetic region (which can be narrower than the width of a Bloch wall in a continuous magnetic thin film). The following approaches have been used to provide magnetic storage media with improved areal density of information storage. These approaches have single bit magnetic domains that are completely separate from each other, either by depositing the magnetic domains as separate islands or by remove material from a continuous magnetic film to physically separate the magnetic domains.

A disk is coated with a seed layer followed by a resist. The resist is patterned to define magnetic domains, exposing the seed layer where magnetic domains are to be formed. A magnetic thin film is then electroplated onto the exposed regions of the seed layer. However, there are problems with the composition and quality of the electrodeposited magnetic films and with the scalability of the process for high volume manufacturing of HDDs. Sputter-deposited Co—Pt and Co—Pd alloy thin films are currently preferred over electrodeposited Co—Pt due to better corrosion resistance and more controllable magnetic properties.

In an alternative process a disk coated with a sputter-deposited magnetic thin film is covered with a layer of resist which is patterned to define magnetic domains. The pattern is transferred into the magnetic thin film by a sputter dry etch process. However, the sputter-etch process leaves an undesirable build-up of residue on the process chamber walls. Furthermore, leaving a residue free disk surface is a challenge following the sputter-etch process. (A very flat, residue-free disk surface is required considering that the read-write head travels only several tens of nanometers above the disk surface at very high speed.) Also, the HDD disks require patterning of magnetic thin films on both sides and many semiconductor type processes and equipment (i.e. sputter etch) can only process one side at once. These problems affect production yields and can contribute to HDD failures. Consequently, there is a need for more production-worthy methods—cost-effective and compatible with high-volume manufacturing—for patterning the magnetic domains.

Another approach is to create non-magnetic regions in a continuous magnetic thin film to separate the magnetic domains. An advantage of such a method is that the surface of the finished disk is planar and better suited for use in an HDD. Such a method is to pattern the magnetic domains using ion implantation to create non-magnetic areas to separate the magnetic domains. The energetic ions disorder the magnetic material, rendering the material non-magnetic. Although, there are some non-magnetic materials, such as ordered FePt₃, which can be made magnetic by ion irradiation, in which case ion irradiation is used to directly define the magnetic domains. However, patterning by ion irradiation can suffer from the following disadvantages: (1) ion implanter tools are configured to irradiate only one side of a substrate at once; (2) and the process is slow, due to the limited ion current available from an ion implanter ion source. Therefore, there remains a need for methods for patterning the magnetic domains which are cost effective and compatible with high volume manufacturing.

Non-volatile memory is computer memory that can retain stored data even when not powered. Examples of non-volatile memory include read-only memory, flash memory, most types of magnetic computer storage devices (for example, hard disks and floppy disks) and optical discs. Non-volatile memory generally either costs more or is slower than volatile random access memory, and is therefore only used primarily for long-term, persistent data storage and not as processing memory. The most widely used form of processing memory today is a volatile form of random access memory (RAM), meaning that when the computer is shut down, anything contained in the RAM is lost. There is a need for faster and cheaper non-volatile memory that can be used as processing memory. Such non-volatile memory would allow for computers that could be turned on and off almost instantly—without the slow start-up and shutdown sequences prevalent in today's computers.

The current standard for non-volatile RAM is NAND Flash, which consists of one transistor and one capacitor per memory element. The density of memory elements is limited by the overall transistor size and the trench between transistors, resulting in a spacing of elements of less than one micron. There is a need for non-volatile RAM with a higher density of memory elements.

Magnetoresistive RAM (MRAM)—a non-volatile RAM which shows considerable promise—is currently under development, but is not yet commercially competitive with standard volatile RAM. There is a need for improved processing methods and designs for MRAM, and non-volatile RAM generally, which will allow cost effective, high throughput, high volume manufacturing.

### SUMMARY OF THE INVENTION

The concepts and methods of the invention allow for high volume manufacturing of magnetic media where the magnetic domains on the disks are directly patterned. Direct patterning of the magnetic domains allows for higher density data storage than is available in continuous magnetic thin films. According to aspects of the invention, a method for defining magnetic domains in a magnetic thin film on a substrate includes: (1) coating the magnetic thin film with a resist; (2) patterning the resist, wherein areas of the magnetic thin film are substantially uncovered; and (3) exposing the magnetic thin film to a plasma, wherein plasma ions penetrate the substantially uncovered areas of the magnetic thin film, rendering the substantially uncovered areas non-magnetic. Methods of patterning the resist include nanoimprint lithography processes.

Methods of the invention may be applied to advantage in high volume manufacturing of thin film magnetic disks used in hard disk drives. Embodiments of the present invention provide high manufacturing throughput by simultaneously processing both sides of the disks using a high throughput plasma ion implantation tool. According to further aspects of the invention, a method for defining magnetic domains in magnetic thin films on both sides of a disk includes: (1) coating both sides of the disk with a resist; (2) patterning the resist, wherein areas of the magnetic thin film are substantially uncovered; and (3) simultaneously exposing the magnetic thin film on both sides of the disk to a plasma, wherein plasma ions penetrate the substantially uncovered areas of the magnetic thin film, rendering the substantially uncovered areas non-magnetic.

Either a double side plasma ion implant or a single side plasma ion implant may be used without departing from the spirit of the invention. In the single side plasma ion implant a first side will be implanted, then the disk will be flipped over and the second side will be implanted.

Embodiments of the invention include a plasma ion implantation tool configured for simultaneous processing of both sides of disks. The tool comprises: (1) a vacuum chamber held at earth potential; (2) a gas inlet valve configured to leak controlled amounts of gas into the chamber; (3) a disk mounting device configured to (a) fit within the chamber, (b) hold a multiplicity of disks, spacing the multiplicity of disks wherein both sides of each of the multiplicity of disks is exposed and (c) make electrical contact to the multiplicity of disks; and (4) a radio frequency signal generator electrically coupled to the disk mounting device and the chamber, whereby a plasma can be ignited in the chamber and the disks are exposed to plasma ions uniformly on both sides.

Embodiments of the invention include a memory device. According to aspects of the invention, a memory device comprises: a first continuous thin film, the first continuous thin film including a first defined array of magnetic domains; wherein the defined magnetic domains are separated by non-magnetic regions of the continuous thin film, and wherein each of the first defined array of magnetic domains. The memory device may further comprise: a second continuous thin film parallel to the first continuous thin film, the second thin film including a second defined array of magnetic domains, wherein each of the second defined magnetic domains overlaps a corresponding one of the first defined magnetic domains; an insulating thin film between the first and second continuous thin films; word lines positioned below the first continuous thin film; and bit lines positioned above the second continuous thin film; wherein the word lines and the bit lines cross over each other at the positions of the first and second defined magnetic domains.

According to further aspects of the invention, a method of fabricating an memory device comprises: (1) depositing a magnetic thin film on a substrate; (2) defining magnetic domains in the magnetic thin film on the substrate, including: (a) coating the magnetic thin film with a resist; (b) patterning the resist, wherein areas of the magnetic thin film are substantially uncovered; and (3) exposing the magnetic thin film to a plasma, wherein plasma ions penetrate the substantially uncovered areas of the magnetic thin film, rendering the substantially uncovered areas non-magnetic; wherein each of the patterned magnetic domains is part of a different magnetic memory element. Memory devices may be fabricated on both sides of a substrate, wherein the magnetic thin films on both sides of the substrate are simultaneously exposed to a plasma, wherein plasma ions penetrate the substantially uncovered areas of the magnetic thin films, rendering the substantially uncovered areas non-magnetic.

### BRIEF DESCRIPTION OF THE DRAWINGS

These and other aspects and features of the present invention will become apparent to those ordinarily skilled in the art upon review of the following description of specific embodiments of the invention in conjunction with the accompanying figures, wherein:

FIG. 1 is a process flow chart, according to embodiments of the invention;

FIG. 2 is a schematic of a process chamber, showing a first disk holder apparatus, according to embodiments of the invention;

FIG. 3 is a second disk holder, according to embodiments of the invention;

FIG. 4 is a cross-sectional representation of the resist after nanoimprint lithography, according to embodiments of the invention;

FIG. 5 is a perspective view of a representation of a memory device, according to embodiments of the invention; and

FIG. 6 is a cross-section of certain embodiments of the memory device of FIG. 5, according to embodiments of the invention.

### DETAILED DESCRIPTION OF THE PREFERRED EMBODIMENTS

The present invention will now be described in detail with reference to the drawings, which are provided as illustrative examples of the invention so as to enable those skilled in the art to practice the invention. Notably, the figures and examples below are not meant to limit the scope of the present invention to a single embodiment, but other embodiments are possible by way of interchange of some or all of the described or illustrated elements. Moreover, where certain elements of the present invention can be partially or fully implemented using known components, only those portions of such known components that are necessary for an understanding of the present invention will be described, and detailed descriptions of other portions of such known components will be omitted so as not to obscure the invention. In the present specification, an embodiment showing a singular component should not be considered limiting; rather, the invention is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the present invention encompasses present and future known equivalents to the known components referred to herein by way of illustration.

In general, embodiments of the present invention contemplate using plasma ion implantation and a resist mask to pattern closely spaced magnetic domains in a magnetic thin film. This method is applicable to hard disk drive fabrication, allowing very high areal density information storage. A tool for implementing this method is described.

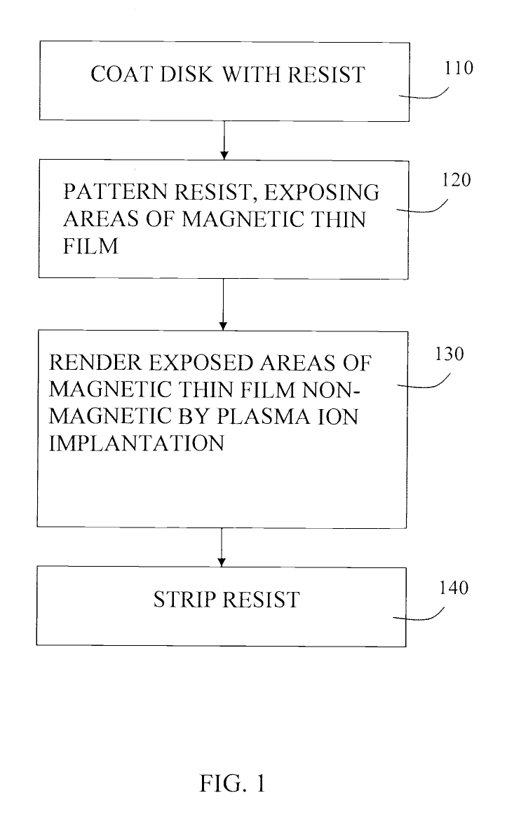

A process according to embodiments of the invention is shown in FIG. 1. The process for forming closely spaced magnetic domains, separated by non-magnetic material, in a magnetic thin film includes the following steps: (1) coat disk with resist (110); (2) pattern resist, substantially exposing areas of the magnetic thin film (120); (3) render substantially exposed areas of the magnetic thin film non-magnetic by plasma ion implantation (130); and (4) strip resist (140). The method may optionally include a descum and ash in the plasma ion implantation chamber, after plasma ion implantation and prior to resist strip. Also, a buff or polish may be included after resist strip to ensure a residue-free surface. For example, a brush scrubber step, such as carried out with a PVA brush, or other appropriate type of brush, may be used. Alternatively, a polyurethane cloth, pad buff or polish may be used.

The above process may also include the extra step of a laser or flash anneal to drive the plasma ion implanted species into the thin film. A rapid thermal anneal or furnace process may also be used. (The laser or flash anneal differs from the rapid thermal anneal or furnace process in that only the surface of the disk is subject to the thermal excursion in the former.) Furthermore, thermal processing can be used to force the implanted species into the grain boundaries in the magnetic thin film. (Each magnetic domain currently comprises many hundreds of individual grains.) The implanted species are locked in place in the grain boundaries so that they do not move during the normal lifetime of the disk.

A method for patterning the resist is a nanoimprint lithography method. There are two well known types of nanoimprint lithography that are applicable to the present invention. The first is thermoplastic nanoimprint lithography (T-NIL), which includes the following steps: (1) coat the substrate with a thermoplastic polymer resist; (2) bring a mold with the desired three-dimensional pattern into contact with the resist and apply a prescribed pressure; (3) heat the resist above its glass transition temperature; (4) when the resist goes above its glass transition temperature the mold is pressed into the resist; and (5) cool the resist and separate the mold from the resist, leaving the desired three-dimensional pattern in the resist.

The second type of nanoimprint lithography is photo nanoimprint lithography (P-NIL), which includes the following steps: (1) a photo-curable liquid resist is applied to the substrate; (2) a transparent mold, with the desired three-dimensional pattern, is pressed into the liquid resist until the mold makes contact with the substrate; (3) the resist is cured in ultraviolet light, becoming a solid; and (4) the mold is separated from the resist, leaving the desired three-dimensional pattern in the resist. In P-NIL the mold is made of a transparent material such as fused silica.

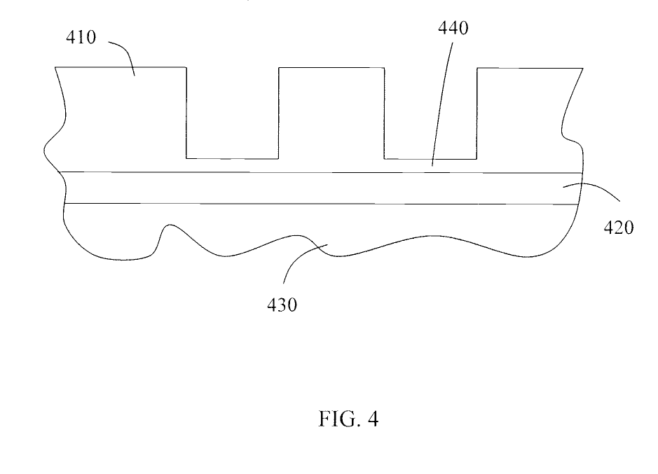

FIG. 4 shows a cross-sectional representation of the resist after nanoimprint lithography. The patterned resist 410 on magnetic thin film 420 on substrate 430 is shown having patterned areas 440 where the resist has been substantially displaced. A typical thickness of resist layer 410 is about 500 nm. However, areas 440 have a small amount of resist left covering the surface of the magnetic thin film. This is typical for a nanoimprint process. When using a photoresist pattern as a mask for ion implantation, it is not necessary for the entire photoresist layer to be removed in the areas where the species will be implanted. However, the remaining layer should be thin enough not to cause a substantial barrier for the implant species. Furthermore, the contrast between the areas with thick resist and thin remaining resist should be large enough so the resist in the areas that have the thick remaining resist is capable of stopping the ion species before they reach the magnetic thin film. Alternatively, the remaining photoresist in areas 440 can be removed with an isotropic resist removal process such as a descum or a slight ash or any other appropriate technique.

The nanoimprint lithography process can be implemented using a full disk nanoimprint scheme, where the mold is large enough to imprint one entire surface. Alternatively, a step and repeat imprint process may be used. The nanoimprint process may also be performed with both sides at once. For example, the disk is first coated with a photoresist layer on both sides. Then the disk goes into a press where molds are pressed against both sides of the disk to imprint the desired pattern on both sides of the disk simultaneously.

Conventional photolithographic processes may also be used, in which case photoresist is spun on the disks, followed by exposure of the resist through a mask, and development of the exposed resist.

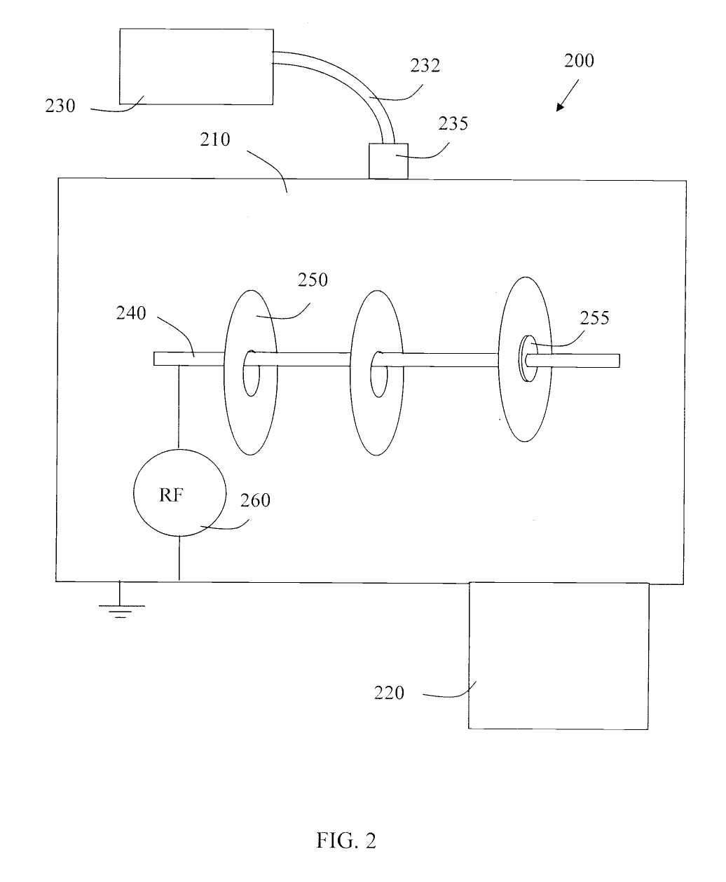

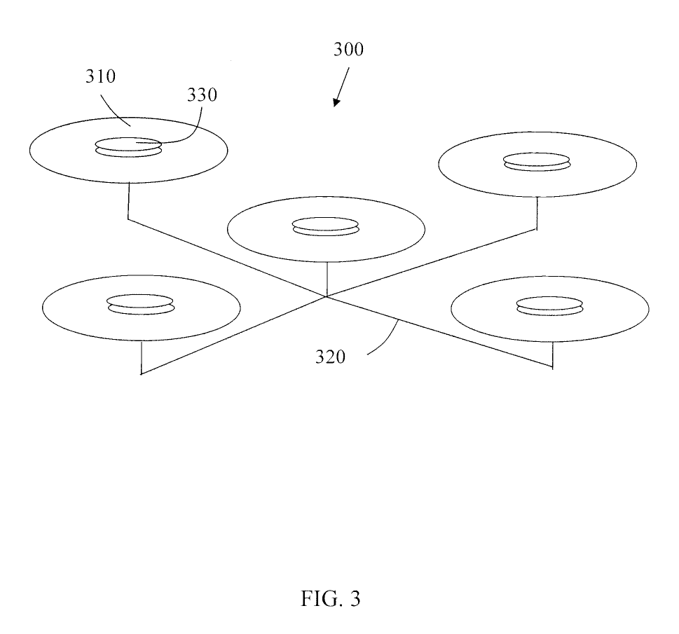

After the patterning step 120 the disks have a patterned resist which leaves areas of the magnetic thin film exposed. The resist protects the remaining surface from the next step—plasma ion implantation 130. Plasma implantation is ideal for providing high implant doses at low energies. Since the sputtered magnetic thin films are typically only tens of nanometers thick, the low ion energies are effective and the high dose provides high throughput. Furthermore, as is clear from FIGS. 2 and 3, plasma ion implantation of both sides of the disks can be carried out at the same time. Although it is expected that a double side plasma ion implant will generally be used, a single side plasma ion implant may be used without departing from the spirit of the invention. In the single side plasma ion implant a first side will be implanted, then the disk will be flipped over, and the second side will be implanted.

A plasma ion implantation tool 200 configured for handling HDD disks is shown in FIG. 2. The chamber 210 is maintained under vacuum by vacuum pump 220. Gas supply 230 is connected by pipe 232 and valve 235 to the chamber 210. More than one gas may be supplied through valve 235 and multiple gas supplies and valves may be used. A rod 240 holds disks 250. A radio frequency (RF) power supply 260 is connected between the rod 240 and the wall of the chamber 210 (the chamber wall is connected to an electrical earth). In addition to the RF power supply an impedance matching device and a power supply for applying a direct current (DC) bias may be included. The rod 240 may be coated with graphite or silicon to protect it from the plasma. Furthermore, the rod and its surface are highly conductive to facilitate a good electrical contact between the rod and the disks. The disks 250 may be fixed in place using clamps 255 or other means; the clamps 255 will not only fix the disks 250 in place but also ensure a good electrical connection between the disks 250 and the rod 240. The rod can carry many disks (only three disks 250 are shown for ease of illustration). Furthermore, the chamber 210 may be configured to hold many rods loaded with disks for simultaneous plasma ion implantation. The rods 240 are readily moved in and out of the chamber 210.

Processing of the disks in the plasma ion implantation tool 200 may proceed as follows: (1) the disks 250 are loaded onto the rod 240; (2) the rod 240 is loaded into the chamber 210; (3) the vacuum pump 220 operates to achieve a desired chamber pressure; (4) a desired gas is leaked into the chamber from gas supply 230 through valve 235 until the desired pressure is reached; (5) the RF power supply 260 is operated so as to ignite a plasma which surrounds the surfaces of all of the disks 250 and the DC power supply can be used to control the energy of the ions that are implanted into the magnetic thin film. RF biasing may also be used.

Ions that can be readily implanted from a plasma and that will be effective in rendering the typical sputtered magnetic thin films, such as Co—Pt and Co—Pd, non-magnetic are: oxygen, fluorine, boron, phosphorus, tungsten, arsenic, hydrogen, helium, argon, nitrogen, vanadium and silicon ions. This list is not intended to be exhaustive—any ion readily formed in a plasma and effective in rendering a thin film non-magnetic (or magnetic in the case of materials such as FePt₃) will suffice. Furthermore, it is expected that suitable ions are those that, with relatively low doses, can change areas of the magnetic thin film into thermally stable non-magnetic areas.

The energy of ions available from a plasma implantation process is in the range of 100 eV to 15 keV. However, for implanting into the magnetic thin films, which are tens of nanometers thick, the desirable energy range is 1 keV to 15 keV. Here it is assumed that singly ionized species are predominant in the plasma.

FIG. 3 shows an alternative holder for plasma ion implantation of the disks in a chamber as shown in FIG. 2. Holder 300 comprises a frame 310 to which the disks 320 are fixed in position by clamps 330, which clamp onto the edges of the holes in the center of the disks. (Note that the inner edges of the disk are not used in the final product, since this is where the spindle is attached to the disk. This is in contrast to the outer edge of the disk which is used in the HDD and therefore must be properly patterned.) The frame 310 and the clamps 330 are configured to make good electrical contact to the disks 320. The holders may be stacked one above another in the chamber to enable high throughput.

Further details of plasma ion implantation chambers and process methods are available in U.S. Pat. Nos. 7,288,491 and 7,291,545 to Collins et al., incorporated by reference herein. The primary difference between the chamber of the present invention and the chamber of Collins et al. is the different configuration for holding the substrates. Those skilled in the art will appreciate how the plasma ion implantation tools and methods of Collins et al. can be utilized in the present invention.

Following the plasma ion implantation step 130 is the resist strip step 140. The resist strip step 140 can be facilitated by a descum and ash in the plasma ion implantation chamber prior to removing the disks. The resist strip step 140 may also be a wet chemical process, such as commonly used for resist strip in the semiconductor industry.

The present invention allows for very short process times—perhaps ten seconds to implant the disks. Input and output vacuum loadlocks will enable rapid transfer of disks in and out of the chamber and avoid losing time for pumpdown, thus allowing for very high throughput. Those skilled in the art will appreciate how automated transfer systems, robotics and loadlock systems can be integrated with the plasma ion implantation apparatus of the present invention.

The present invention is not restricted to HDDs, but is applicable to other magnetic memory devices such as magnetic core memories and magnetoresistive random access memories (MRAMs). The present invention may be used to define the magnetic memory elements of these memory devices.

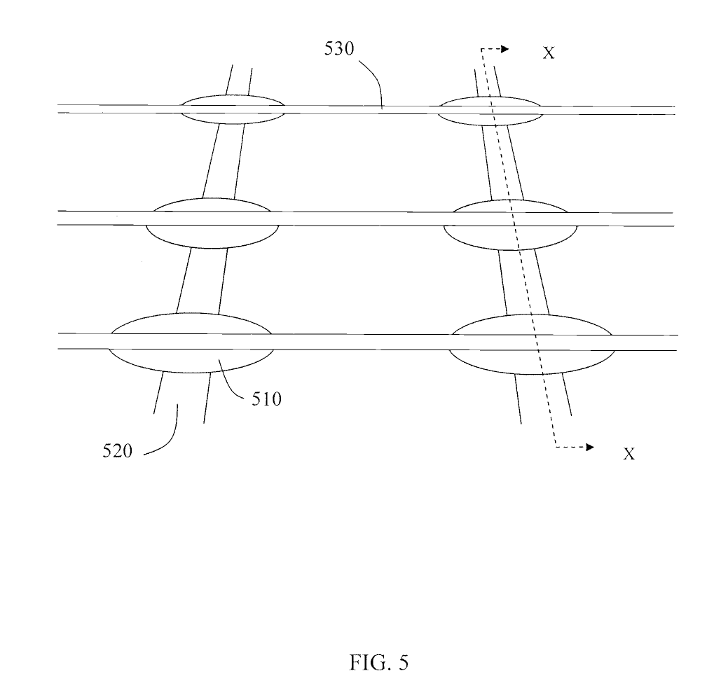

FIG. 5 shows a representation of a magnetic memory device with a cross-point architecture. In the cross-point architecture, a magnetic memory element 510 is situated at each intersection of the word lines 520 and bit lines 530. The magnetic memory elements 510 are actually part of continuous thin films, but for ease of illustration the continuous thin films are not shown in FIG. 5. In embodiments of the present invention, the magnetic memory elements 510 are fabricated using the process described above, with reference to FIGS. 1-4. The magnetic memory elements 510 are shown in FIG. 5 to be roughly circular; however, the elements 510 may be patterned in a wide variety of shapes, as desired, including ovals, squares and rectangles. In FIG. 5, only six magnetic memory elements are shown, but a typical memory array will consist of orders of magnitude more elements. The magnetic memory elements 510 in their simplest embodiments comprise a single layer of magnetic material. Such embodiments of the present invention include memory devices which are in effect scaled-down versions of the original magnetic core memories. For these embodiments, the memory cells 510 shown in FIG. 5 will be single magnetic domains. This memory configuration allow for vertical stacking of memory devices, to create three-dimensional memory devices. Those skilled in the art will appreciate how embodiments of the present invention can be used to fabricate these three-dimensional memory devices. A fabrication method for this memory device may be as follows. Word lines 520 are formed on a substrate. A magnetic thin film is deposited over the substrate and word lines 520. The first magnetic thin film is processed, as described above, rendering areas unprotected by resist non-magnetic—leaving domains of magnetic material 510. The bit lines 530 are formed on top of the processed magnetic thin film. The word lines 520 and bit lines 530 are lithographically aligned to form cross-overs at each memory element 510. The write and read mechanisms of a magnetic core memory are well known to those skilled in the art.

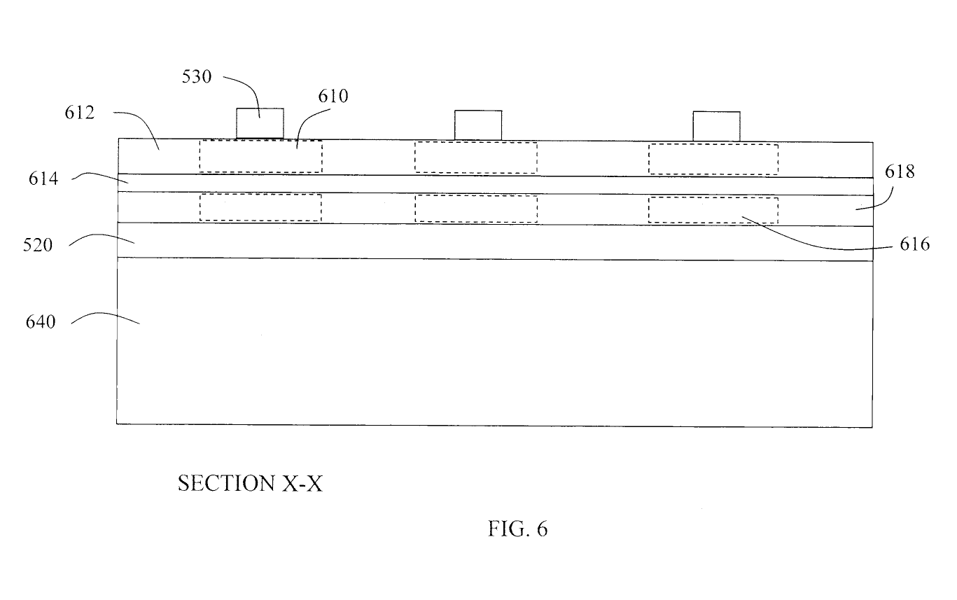

In further embodiments of the present invention, the memory device is an MRAM and the magnetic memory elements are magnetic tunnel junctions, which comprise at least three layers: (1) a lower layer which has a fixed magnetization (unchanged during the write and read processes); (2) an upper layer which has a magnetic orientation which is changeable during the write process; and (3) an insulating thin film between the two magnetic layers. See FIG. 6. Alternatively, the elements 510 may be fabricated to allow use of the “toggle” mode, as is well known in the art. Furthermore, the MRAM device of FIG. 5 may be operated using spin transfer switching, as is well known in the art. These MRAM configurations allow for vertical stacking of memory devices, to create three-dimensional memory devices. Those skilled in the art will appreciate how embodiments of the present invention can be used to fabricate these three-dimensional MRAM memory devices. The write and read mechanisms of an MRAM such as shown in FIGS. 5 and 6 are well known to those skilled in the art.

In order to allow the fabrication of very high density arrays of magnetic memory elements, fabrication methods of the present invention may be used to form magnetic memory elements as small as approximately 10 nanometers in diameter, with densities exceeding 1 Tb/in². Furthermore, the word lines 520 and bit lines 530 may be comprised of nanowires.

FIG. 6 shows a vertical cross-section X-X through MRAM memory devices, which are certain embodiments of the memory device of FIG. 5. FIG. 6 shows the complete thin films 612 and 618 which contain the magnetic domains 610 and 616 which make up the magnetic memory elements 510. There is an insulating thin film 614 between the two thin films 612 and 618. The word lines 520 are on a substrate 640 and the bit lines 530 are on top of the thin film 612. The MRAM structure of FIGS. 5 and 6 may be fabricated as follows. Word lines 520 are formed on the substrate 640. A first magnetic thin film is deposited over the substrate and word lines 520. The first magnetic thin film is processed, as described above, rendering the areas 618 non-magnetic—leaving domains of magnetic material 616. The thin film of insulator 614 is deposited on top of the processed first magnetic thin film. A second magnetic thin film is deposited on top of the insulator 614. The second magnetic thin film is processed, as described above, rendering the areas 612 non-magnetic—leaving domains of magnetic material 610. During processing, the domains 610 and 616 are lithographically aligned to form the magnetic memory elements 510. The bit lines 530 are formed on top of the processed second magnetic thin film. The word lines 520 and bit lines 530 are lithographically aligned to form crossovers at each memory element 510.

Although the present invention has been particularly described with reference to the preferred embodiments thereof it should be readily apparent to those of ordinary skill in the art that changes and modifications in the form and details may be made without departing from the spirit and scope of the invention. It is intended that the appended claims encompass such changes and modifications.

What is claimed is:

1. A method for fabricating memory devices, comprising:
depositing a magnetic thin film on a substrate;
defining magnetic domains in said magnetic thin film on said substrate, including:
coating said magnetic thin film with a resist;
patterning said resist, wherein areas of said magnetic thin film are substantially uncovered; and
exposing said magnetic thin film to a plasma, wherein plasma ions penetrate said substantially uncovered areas of said magnetic thin film, rendering said substantially uncovered areas non-magnetic;
wherein each of said patterned magnetic domains is part of a different magnetic memory element.

2. The method of claim 1, wherein said patterning is nanoimprint patterning.

3. The method of claim 1, wherein said plasma comprises oxygen, fluorine, boron, phosphorus, tungsten, arsenic, hydrogen, helium, argon, nitrogen, carbon or silicon ions.

4. The method of claim 1, further comprising, after exposing said magnetic thin film to a plasma, annealing said magnetic thin film, whereby the implanted ions are driven to a desired depth in said magnetic thin film.

5. The method of claim 4, wherein said anneal is implemented by a laser.

6. The method of claim 1, further comprising, after said exposing, stripping said resist.

7. The method of claim 1, wherein said plasma is generated by connecting a radio frequency generator between said magnetic thin film and a vacuum chamber wall, said substrate being positioned in a vacuum chamber.

8. The method of claim 7, wherein said exposing said magnetic thin film to said plasma includes applying a direct current bias between said thin film and said vacuum chamber wall.

9. The method of claim 7, wherein said exposing said magnetic thin film to said plasma includes applying a radio frequency bias between said thin film and said vacuum chamber wall.

10. The method of claim 1, further comprising:
before said depositing, forming word lines on said substrate; and
after said exposing, forming bit lines on top of said magnetic domains;
wherein said word lines and said bit lines cross over each other at the positions of said patterned magnetic domains.

11. A method for fabricating memory devices, comprising:
providing a substrate with magnetic thin films on both surfaces;
coating both sides of said substrate with a resist;
patterning said resist, wherein areas of said magnetic thin films are substantially uncovered; and
simultaneously exposing said magnetic thin films on both sides of said substrate to a plasma, wherein plasma ions penetrate said substantially uncovered areas of said magnetic thin films, rendering said substantially uncovered areas non-magnetic;
wherein each of said magnetic domains is part of a different magnetic memory element.

12. The method as in claim 11, wherein said patterning is nanoimprint patterning.

13. The method as in claim 12, wherein said patterning is on both sides of said substrate at once.

14. A memory device, comprising:
a first continuous thin film, said first continuous thin film including a first defined array of magnetic domains;
wherein said defined magnetic domains are separated by non-magnetic regions of said continuous thin film, and wherein each of said first defined array of magnetic domains is part of a different magnetic memory element.

15. The memory device as in claim 14, further comprising:
word lines positioned below said first continuous thin film; and
bit lines positioned above said first continuous thin film;
wherein said word lines and said bit lines cross over each other at the positions of said first defined magnetic domains.

16. The memory device as in claim 14, further comprising:
a second continuous thin film parallel to said first continuous thin film, said second thin film including a second defined array of magnetic domains;
wherein each of said second defined magnetic domains overlaps a corresponding one of said first defined magnetic domains.

17. The memory device as in claim 16, further comprising an insulating thin film between said first and second continuous thin films.

18. The memory device as in claim 16, further comprising:
word lines positioned below said first continuous thin film; and
bit lines positioned above said second continuous thin film;
wherein said word lines and said bit lines cross over each other at the positions of said first and second defined magnetic domains.
